(19) United States
(12) Patent Application Publication
(10) Pub. No.: US 2023/0302603 A1
(43) Pub. Date: Sep. 28, 2023

(54) PROCESSING DEVICE

(71) Applicant: TOKYO SEIMITSU CO., LTD., Tokyo (JP)

(72) Inventors: Fumio MASE, Tokyo (JP); Masaki KANAZAWA, Tokyo (JP)

(21) Appl. No.: 17/902,995

(22) Filed: Sep. 5, 2022

(30) Foreign Application Priority Data
Mar. 24, 2022 (JP) 2022-047976

(51) Int. Cl. B24B 27/00; B24B 7/22; B24B 49/00

(52) U.S. Cl. CPC B24B 27/0046; B24B 7/228; B24B 49/00

(57) ABSTRACT

A processing device that alleviates the influence of rough grinding and performs fine grinding and processes the work with a satisfactory precision. An index table includes a plurality of chucks for holding a work and transports the work to a rough grinding stage with a rough grinding means for rough grinding the work, a medium grinding stage with a medium grinding means for medium grinding the work, and a fine grinding stage with a fine grinding means for fine grinding the work. A first column extends over the index table and one of the rough grinding means or the fine grinding means is installed. A second column extends over the index table and is independent from the first column, and the medium grinding means is installed and the other one of the rough grinding means or the fine grinding means is arranged parallel to the medium grinding means.

### TECHNICAL FIELD

The present invention relates to a processing device that performs rough grinding, medium grinding and fine grinding on a work in order.

### BACKGROUND ART

In the field of semiconductor manufacturing, back-surface grinding for grinding the back surface of the work is performed to form a semiconductor wafer (hereinafter referred to as “work”) such as a silicon wafer to a thin film.

As a processing device that performs the back-surface grinding of the work, Patent Document 1 discloses an in-feed type grinding device that continuously performs rough grinding and fine grinding on a work in a state where a rough grinding spindle and a fine grinding spindle are arranged on a column provided to extend over an index table to suppress axis-tilting of a grinding stone at the time of grinding.

### PRIOR ART REFERENCES

### Patent Documents

[Patent document 1] International Patent Publication No. 2017/094646

### DISCLOSURE OF THE INVENTION

### Problems to be Solved by the Invention

However, in the processing device described in Patent Document 1 as described above, as the rough grinding spindle and the fine grinding spindle are arranged on the same column, vibration generated at the time of rough grinding, in which a grinding removal amount is relatively large, may be transmitted to the fine grinding spindle through the column and a fine grinding stone may unnecessarily cut into the work, or the column or a base may deform due to the load at the time of the rough grinding and a fine grinding stone may cut into the work at an unintended inclination, whereby the work may not be processed with a satisfactory precision.

Thus, a technical problem to be solved arises, which is to alleviate the influence of rough grinding and perform fine grinding and process the work at a satisfactory precision, and the present invention aims to solve such a problem.

### Means for Solving the Problems

The present invention has been proposed to achieve the above object, and provides a processing device that performs rough grinding, medium grinding, and fine grinding on a work in order, the processing device including an index table that includes a plurality of chucks for adsorbing and holding the work and transports the work in order of a rough grinding stage provided with a rough grinding means for rough grinding the work, a medium grinding stage provided with a medium grinding means for medium grinding the work, and a fine grinding stage provided with a fine grinding means for fine grinding the work; a first column provided to extend over the index table and in which one of the rough grinding means or the fine grinding means is installed; and a second column provided to extend over the index table and provided independent from the first column, and in which the medium grinding means is installed and the other one of the rough grinding means or the fine grinding means is arranged parallel to the medium grinding means.

### Effect of the Invention

In the present invention, the first column and the second column are provided independent from each other, the rough grinding means that causes a large displacement in the processing device due to reaction at the time of processing is provided on one of the first column or the second column, and the fine grinding means that greatly affects a finish shape of the work is provided on the other one of the first column or the second column, so that the work can be processed with a satisfactory precision.

### BRIEF DESCRIPTION OF THE DRAWINGS

FIG. 1 is a perspective view illustrating a processing device according to one embodiment of the present invention.

FIG. 2 is a plan view illustrating a processing device in which the configuration of one part is omitted.

FIG. 3 is a plan view illustrating an index table.

FIG. 4 is a longitudinal cross-sectional view of the processing device in a medium grinding stage.

FIG. 5 is a plan view illustrating a processing device in which some configurations are omitted in a fine grinding independent layout.

FIG. 6 is a contour diagram showing the displacement generated in the processing device in the processing device of a rough grinding independent layout.

FIG. 7 is a contour diagram showing the displacement generated in the index table and a base in the processing device of the rough grinding independent layout.

FIG. 8 is a contour diagram showing the displacement generated in the processing device in the processing device of the fine grinding independent layout.

FIG. 9 is a contour diagram showing the displacement generated in the index table and the base in the processing device of the fine grinding independent layout.

FIG. 10 is a diagram showing actual measurement result of the shape of a work processed by the processing device of the rough grinding independent layout.

FIG. 11 is a diagram showing actual measurement result of the shape of a work processed by the processing device of the fine grinding independent layout.

FIG. 12 is a graph showing vibration data of a medium grinding means in the processing device of the rough grinding independent layout.

FIG. 13 is a graph showing vibration data of a fine grinding means in the processing device of the rough grinding independent layout.

FIG. 14 is a graph showing vibration data of the medium grinding means in the processing device of the fine grinding independent layout.

FIG. 15 is a graph showing vibration data of the fine grinding means in the processing device of the fine grinding independent layout.

### BEST MODE FOR CARRYING OUT THE INVENTION

Hereinafter, a processing device 1 according to one embodiment of the present invention will be described based on the drawings. Note that in the following example, when referring to the number of constituent elements, numerical value, amount, range, and the like, they are not limited to a specific number other than when clearly indicated in particular and when clearly limited to a specific number in principle, and may be greater than or equal to or less than or equal to a specific number.

When referring to the shape and positional relationship of the constituent elements and the like, they include those that are substantially approximate to or are similar to the shape, and the like other than when clearly indicated in particular and when clearly considered otherwise in principle.

Furthermore, the drawings may be exaggerated such as by enlarging a characteristic portion to facilitate the understanding of the feature, and the dimensional ratio and the like of the constituent elements may not necessarily be the same as the actual dimensional ratio. Moreover, in the cross-sectional view, hatching of some constituent elements may be omitted to facilitate the understanding of a cross-sectional structure of the constituent element.

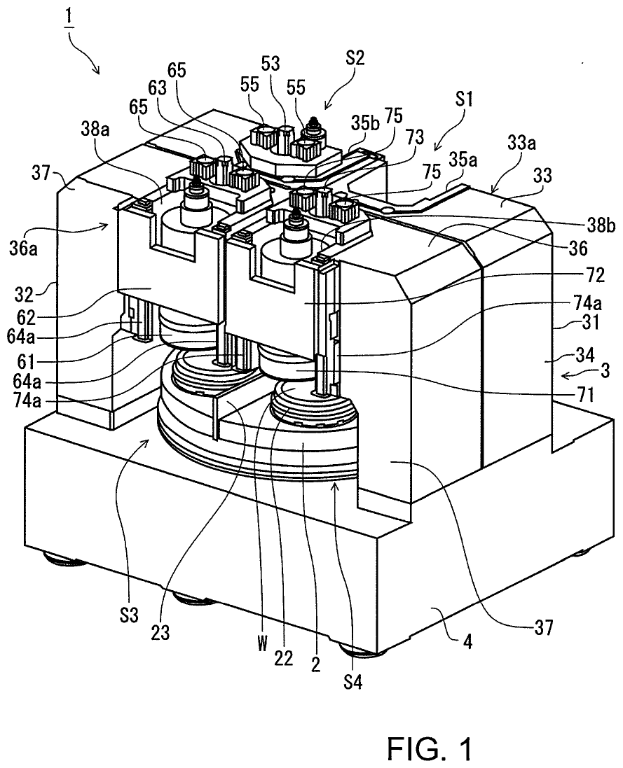

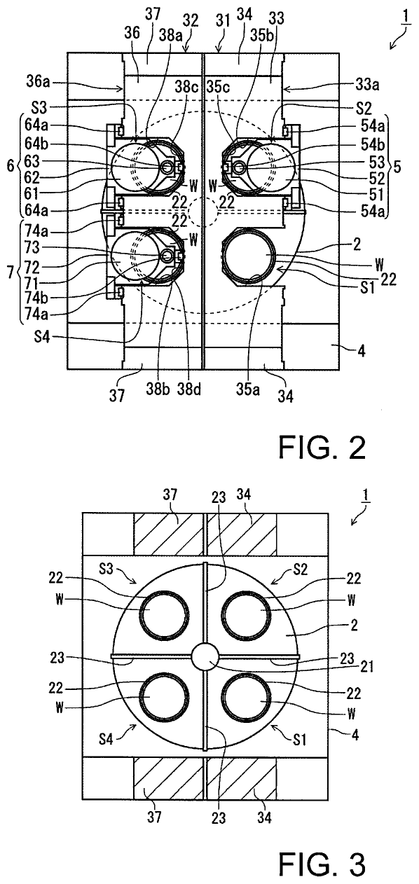

FIG. 1 is a perspective view illustrating a configuration of the processing device 1. FIG. 2 is a plan view of the processing device 1 in which one part is omitted. FIG. 3 is a plan view illustrating an index table 2.

The processing device 1 can grind a plurality of works W in parallel, and grinds a back surface of a work W in a step wise manner with three grinding stones to process into a desired shape. The work W subjected to the grinding process using the processing device 1 is suitably that which exhibits high hardness and high brittleness such as a silicon wafer, a silicon carbide wafer, and the like, but is not limited thereto. Furthermore, the work W may be a work including two layers such as a wafer attached with a soft protective tape or a wafer supported by a hard support substrate.

The processing device 1 includes an index table 2, a main unit 3 disposed above the index table 2, and a base 4 on which the index table 2 and the main unit 3 are placed.

The index table 2 includes four chucks 22 arranged at an interval of 90 degrees on a concentric circle having a rotation shaft 21 as a center. The index table 2 rotates about the rotation shaft 21, and transfers the chuck 22 among a transport in/out stage S1, a rough grinding stage S2, a medium grinding stage S3, and a fine grinding stage S4. Note that the rotating direction of the index table 2 is rotatable in either direction, clockwise or counterclockwise, with the rotation shaft 21 as the center when viewed in a plane. A vacuum source (not shown) is connected to each chuck 22, so that the work W placed on the chuck 22 is adsorbed and held by negative pressure. The chuck 22 is coupled to a motor (not shown) to be rotatable.

A partition plate 23 is arranged between the chucks 22, which partition plate 23 suppresses cooling water and the like used in each stage from scattering to the adjacent stages.

The main unit 3 includes an arch-shaped first column 31 and second column 32 respectively arranged to extend over the index table 2. The first column 31 and the second column 32 have a wider diameter than the index table 2 and are formed to have high rigidity. The first column 31 and the second column 32 are provided independently, so that vibration generated in one of the columns is suppressed from affecting the other column.

The first column 31 includes a base portion 33 formed to a substantially E-shape in plan view, and two supporting columns 34 provided upright from the base 4 and respectively coupled to an end of the base portion 33.

The base portion 33 is bridged above the transport in/out stage S1 and the rough grinding stage S2. The base portion 33 is provided with two grooves 35a, 35b formed over a vertical direction so as to open to a rear surface 33a. The grooves 35a, 35b are provided so that the chuck 22 fits therein when viewed in a plane, and are respectively disposed above the transport in/out stage S1 and above the rough grinding stage S2.

The transport in/out stage S1 is a stage for transporting the work W onto the chuck 22 and extracting the work W from the chuck 22 by a transport device or the like (not shown). The transport in/out stage S1 is exposed at the side of the first column 31, so that the transport device or the like can smoothly access the chuck 22 without interfering with the first column 31 when transporting the work W into the chuck 22 or transporting the work W out from the chuck 22.

The rough grinding stage S2 is a stage for rough grinding the work W. A rough grinding means 5 is provided in the groove 35b.

The rough grinding means 5 includes a rough grinding stone 51, a first spindle 52 in which the rough grinding stone 51 is attached to a lower end, and a first spindle feeding mechanism 53 for raising and lowering the first spindle 52 in the vertical direction. Furthermore, three linear guides serving as first guides that are provided on a rear surface 33a of the first column 31 and a far surface 35c of the groove 35b, and support the first spindle 52 so as to be slidable in the vertical direction are provided. The first guide is a front guide 54a respectively arranged on both sides of the rear surface 33a with the groove 35b in between, and a rear guide 54b arranged on the far surface 35c of the groove 35b. Furthermore, the rough grinding means 5 is provided with a first constant-pressure cylinder 55.

The second column 32 includes a base portion 36 formed to a substantially E-shape in plan view, and two supporting columns 37 provided upright from the base 4 and respectively coupled to an end of the base portion 36.

The base portion 36 is bridged above the medium grinding stage S3 and the fine grinding stage S4. The base portion 36 is provided with two grooves 38a, 38b formed over a vertical direction so as to open to a front surface 36a. The grooves 38a, 38b are provided so that the chuck 22 fits therein when viewed in a plane, and are respectively disposed above the medium grinding stage S3 and above the fine grinding stage S4.

The medium grinding stage S3 is a stage for medium grinding the work W. A medium grinding means 6 is provided in the groove 38a.

The medium grinding means 6 includes a medium grinding stone 61, a second spindle 62 in which the medium grinding stone 61 is attached to a lower end, and a second spindle feeding mechanism 63 for raising and lowering the second spindle 62 in the vertical direction. Furthermore, three linear guides serving as second guides that are provided on a front surface 36a of the second column 32 and a far surface 38c of the groove 38a, and support the second spindle 62 so as to be slidable in the vertical direction are provided. The second guide is a front guide 64a respectively arranged on both sides of the front surface 36a with the groove 38a in between, and a rear guide 64b arranged on the far surface 38c of the groove 38a. Moreover, the medium grinding means 6 is provided with a second constant-pressure cylinder 65.

The fine grinding stage S4 is a stage for fine grinding the work W. A fine grinding means 7 is provided in the groove 38b.

The fine grinding means 7 includes a fine grinding stone 71, a third spindle 72 in which the fine grinding stone 71 is attached to a lower end, and a third spindle feeding mechanism 73 for raising and lowering the third spindle 72 in the vertical direction. Furthermore, three linear guides serving as third guides that are provided on a front surface 36a of the second column 32 and a far surface 38d of the groove 38b, and support the third spindle 72 so as to be slidable in the vertical direction are provided. The third guide is a front guide 74a respectively arranged on both sides of the front surface 36a with the groove 38b in between, and a rear guide 74b arranged on the far surface 38d of the groove 38b. Moreover, the fine grinding means 7 is provided with a third constant-pressure cylinder 75.

When the rough grinding stone 51 and the fine grinding stone 71 are exchanged, the rough grinding stage S2 and the fine grinding stage S4 can be relocated. Which one of the rough grinding stone 51 or the fine grinding stone 71 to arrange on the first column 31 and the other to arrange on the second column 32 is set according to the configuration of the work W.

The operation of the processing device 1 is controlled by a control unit (not shown). The control unit controls each of the constituent elements that constitute the processing device 1. The control unit is configured by, for example, a CPU, a memory and the like. Note that the functions of the control unit may be realized by controlling using software or may be realized by operating using hardware.

Thus, the processing device 1 feeds the work W adsorbed and held by the chuck 22 of the transport in/out stage S1 in the order of the rough grinding stage S2, the medium grinding stage S3, and the fine grinding stage S4 while being placed on the same chuck 22. Furthermore, the chuck 22 that is adsorbs and holds the work W can be formed to high rigidity compared to other work holding devices such as a belt conveyor. Therefore, the throughput of the grinding process can be improved and the work W can be grinding processed to high quality.

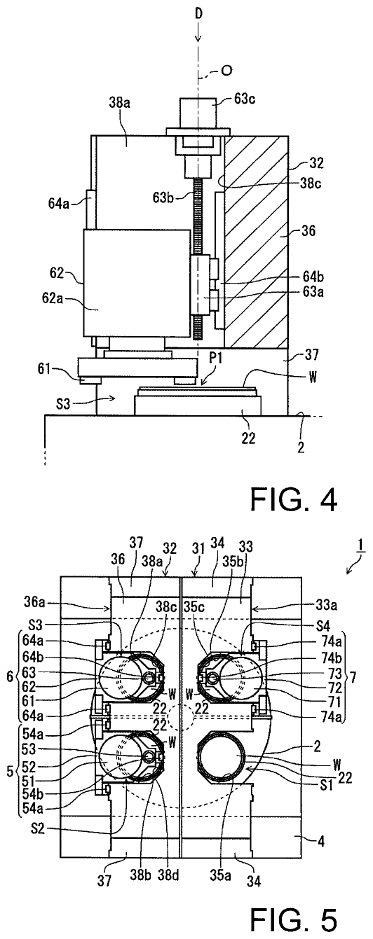

Next, specific configurations of the rough grinding means 5, the medium grinding means 6, and the fine grinding means 7 will be described. Note that the configurations of the rough grinding means 5, the medium grinding means 6, and the fine grinding means 7 are substantially common, and hence the medium grinding means 6 will be representatively described below, and redundant description will be omitted for the rough grinding means 5 and the fine grinding means 7. FIG. 4 is a longitudinal cross-sectional view of the processing device 1 in the medium grinding stage S3.

The medium grinding stone 61 is configured by disposing a plurality of cup-type grinding stones at the lower end in a circumferential direction.

The second spindle 62 includes a saddle 62a in which the medium grinding stone 61 is attached to a lower end, and a motor (not shown) provided in the saddle 62a to rotate the medium grinding stone 61.

The second spindle feeding mechanism 63 includes a nut 63a for coupling the saddle 62a and the second guide 64 arranged on the rear side, a ball screw 63b for raising and lowering the nut 63a, and a motor 63c for rotating the ball screw 63b.

When the motor 63c is driven to forward rotate the ball screw 63b, and the nut 63a is lowered in a feeding direction D of the ball screw 63b parallel to the vertical direction, the saddle 62a lowers. The feeding direction D of the ball screw 63b is on a straight line parallel to the vertical direction that passes through a processing point P1 where the medium grinding stone 61 processes the work W. In other words, the rotation axis O of the ball screw 63b and the processing point P1 of the medium grinding stone 61 are arranged on substantially the same straight line in the vertical direction.

The main unit 3 is provided with an in-process gauge (not shown) for measuring the thickness of the work W. When the thickness of the work W measured by the in-process gauge reaches a desired value, the motor 63c is driven to reverse rotate the ball screw 63b, and the saddle 62a coupled to the nut 63a is raised, so that the work W and the medium grinding stone 61 separate.

As illustrated in FIG. 1, one second constant-pressure cylinder 65 is provided on both sides of the horizontal direction with the nut 63a in between. The second constant-pressure cylinder 65 has the second spindle 62 and the second spindle feeding mechanism 63 suspended in the groove 38a. Specifically, the lower end of a piston rod of the second constant-pressure cylinder 65 is coupled to the nut 63a. As the second constant-pressure cylinder 65 is provided on both sides in the horizontal direction with the second spindle feeding mechanism 63 in between, the second spindle feeding mechanism 63 is regulated from tilting in the horizontal direction when the second spindle feeding mechanism 63 is raised.

The second constant-pressure cylinder 65 is an air cylinder adopting a known configuration including a cylinder, a piston, a piston rod, a compressor, and the like (not shown). The second constant-pressure cylinder 65 raises the piston so as to push back the compressed air filled inside the cylinder of the second constant-pressure cylinder 65 when a thrust force acting on the medium grinding stone 61 at the time of the grinding process is transmitted to the piston rod. The driving pressure of the second constant-pressure cylinder 65 is set to lower than or equal to a value corresponding to the thrust force acting on the medium grinding stone 61 when the medium grinding stone 61 cuts in by a critical cutting depth (Dc value) of the work W.

When the thrust force acting on the medium grinding stone 61 becomes excessively large as a result of the medium grinding stone 61 cutting in deeper than a desired grinding amount (e.g., Dc value), the second spindle 62 and the second spindle feeding mechanism 63 are temporarily raised, and the medium grinding stone 61 is suppressed from cutting in by greater than or equal to the Dc value. Since the grinding process is performed at a constant pressure by the own weight of the medium grinding means 6, the work W is grinded in a ductile mode in a so-called floating state in which the abrasive grains of the medium grinding stone 61 do not come into contact excessively with the work W during the processing.

The second guide 64 is, for example, a linear guide. The second guide 64 is a front guide 64a respectively arranged on both sides of the front surface 36a with the groove 38a in between and a rear guide 64b arranged on the far surface 38c of the groove 38a. The saddle 62a is directly attached to the front guide 64a. Furthermore, the saddle 62a is attached to the rear guide 64b by way of the nut 63a.

The front guide 64a and the rear guide 64b are provided parallel to each other along the vertical direction, and regulate the saddle 62a to move along the vertical direction. In addition, the front guide 64a and the rear guide 64b have the center of gravity of the second spindle 62 arranged within a triangle formed by the front guides 64a and the rear guide 64b when viewed in a plane, so that axis-tilting of the medium grinding means 6 is suppressed.

Next, a procedure of adjusting the arrangement of the rough grinding stone 51 and the fine grinding stone 71 to grind the work W according to the configuration of the work W will be described.

The rough grinding stone 51 and the fine grinding stone 71 can be exchanged on the first column 31 or the second column 32 according to the configuration of the work W. Hereinafter, the processing device 1 of when the rough grinding means 5 is provided on the first column 31 is referred to as “rough grinding independent layout”, and the processing device 1 of when the fine grinding means 7 is provided on the first column 31 is referred to as “fine grinding independent layout”.

In other words, as illustrated in FIG. 2, in the processing device 1 of the rough grinding independent layout, the rough grinding means 5 is arranged on the first column 31, the medium grinding means 6 and the fine grinding means 7 are arranged on the second column 32, and the index table 2 rotates in a counterclockwise direction on the plane of drawing of FIG. 2 to process the work W in the order of the rough grinding, the medium grinding, and the fine grinding.

On the other hand, as illustrated in FIG. 5, in the processing device 1 of the fine grinding independent layout, the fine grinding means 7 is arranged on the first column 31, the rough grinding means 5 and the medium grinding means 6 are arranged on the second column 32, and the index table 2 rotates in a clockwise direction on the plane of drawing of FIG. 5 to process the work W in the order of the rough grinding, the medium grinding, and the fine grinding.

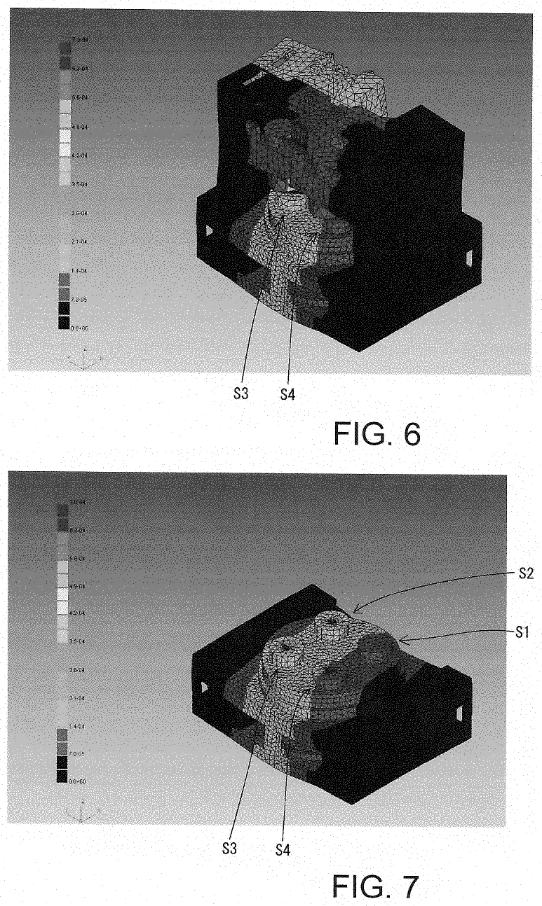

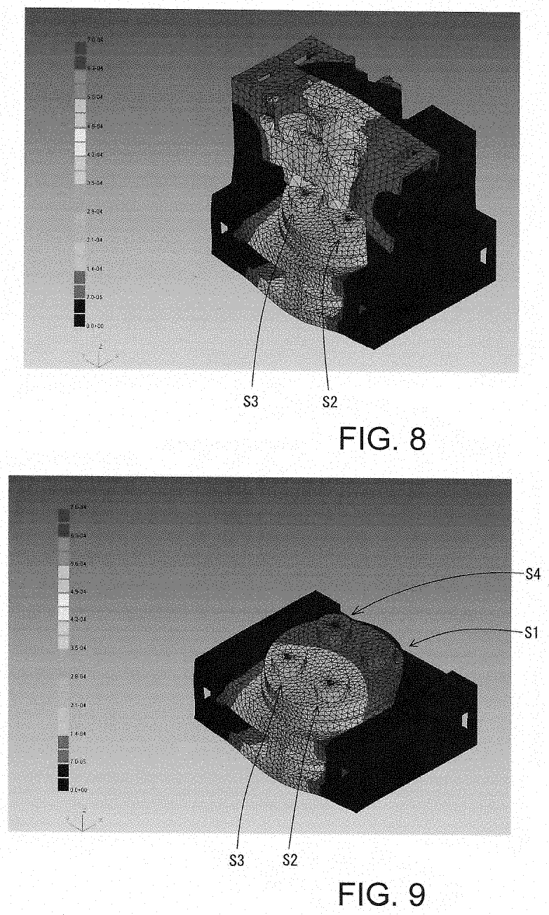

FIG. 6 is a contour diagram showing the analysis result of the displacement generated in the processing device 1 at the time of processing in the rough grinding independent layout. FIG. 7 is a contour diagram showing the analysis result of the displacement generated in the index table 2 and the base 4 at the time of processing in the rough grinding independent layout. FIG. 8 is a contour diagram showing the analysis result of the displacement generated in the processing device 1 at the time of processing in the fine grinding independent layout. FIG. 9 is a contour diagram showing the analysis result of the displacement generated in the index table 2 and the base 4 at the time of processing in the fine grinding independent layout.

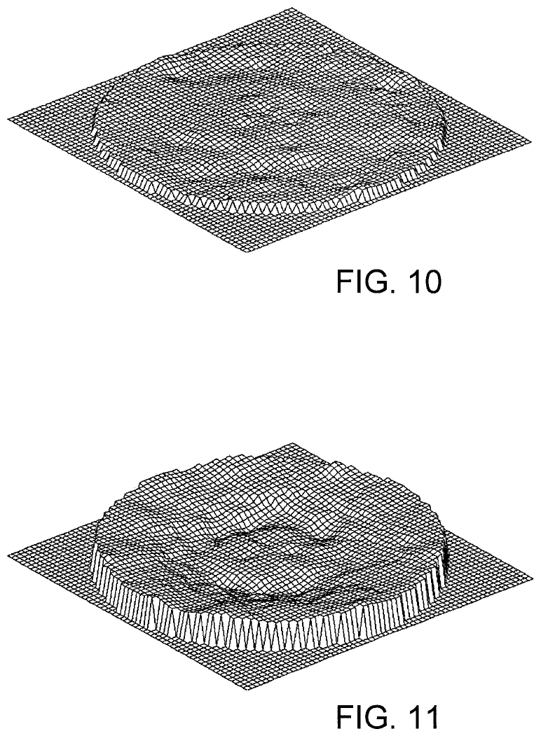

Furthermore, FIG. 10 shows the thickness variation within the processed work W surface processed by the processing device 1 of the rough grinding independent layout, and FIG. 11 shows the thickness variation within the processed work W surface processed by the processing device 1 of the fine grinding independent layout.

According to FIGS. 6 and 8, it can be seen that a large displacement is generated at the periphery of the rough grinding means 5 in both the rough grinding independent layout and the fine grinding independent layout. Furthermore, according to FIG. 7, in the rough grinding independent layout, the displacement at the periphery of the fine grinding means 7 that affects the shape of the processed work W the most is substantially equal, and as shown in FIG. 10, a work W with a small thickness variation within the work W surface can be obtained. On the other hand, according to FIG. 9, in the fine grinding independent layout, the displacement at the periphery of the fine grinding means 7 is unequal, and as shown in FIG. 11, the thickness variation within the work W surface tends to be large.

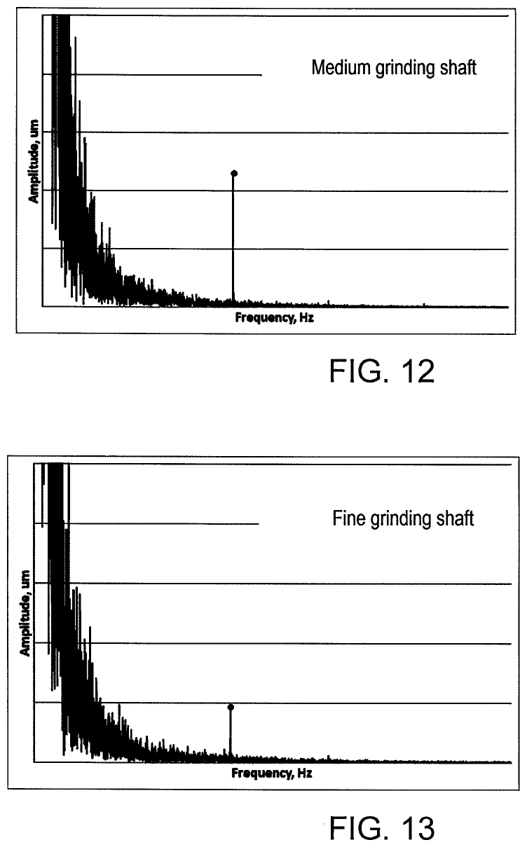

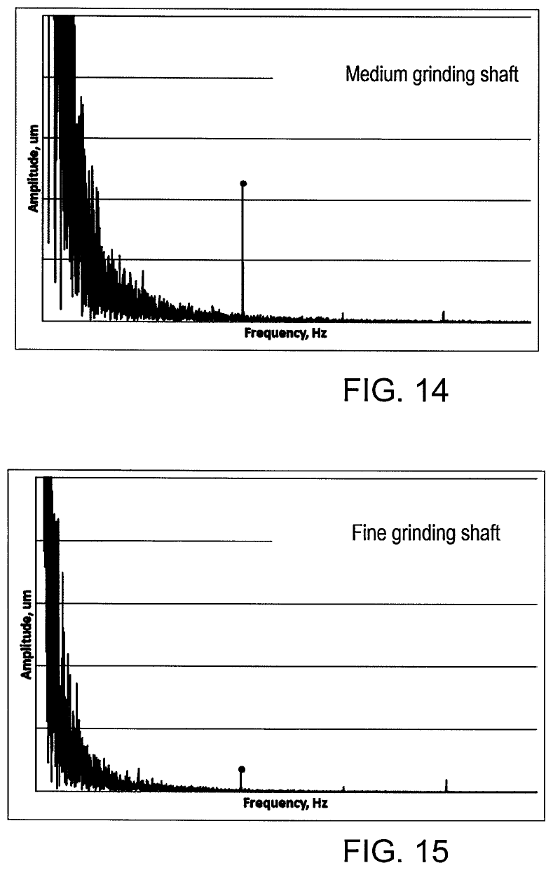

FIG. 12 shows a relationship between the amplitude and the frequency of the vibration in the vertical direction of the second spindle 62 in the rough grinding independent layout, and FIG. 13 shows a relationship between the amplitude and the frequency of the vibration in the vertical direction of the third spindle 72 in the rough grinding independent layout. Furthermore, FIG. 14 shows a relationship between the amplitude and the frequency in the vertical direction of the second spindle 62 in the fine grinding independent layout, and FIG. 15 shows a relationship between the amplitude and the frequency in the vertical direction of the third spindle 72 in the fine grinding independent layout.

It can be seen that the vibration of the second spindle 62 indicated with a black point in FIG. 12 and the vibration of the third spindle 72 indicated with a black point in FIG. 13 are the same frequency, and that the vibration of the second spindle 62 is propagated to the third spindle 72.

Similarly, it can be seen that the vibration of the second spindle 62 indicated with a black point in FIG. 14 and the vibration of the third spindle 72 indicated with a black point in FIG. 15 are the same frequency, and that the vibration of the second spindle 62 is propagated to the third spindle 72. However, it can be seen that the propagated vibration from the second spindle 62 to the third spindle 72 in the fine grinding independent layout is small and reduced as compared with that in the rough grinding independent layout. This is because the first column 31 and the second column 32 are provided independent from each other.

As described above, in consideration of the magnitude of the displacement at the time of grinding and the influence of the propagated vibration from the medium grinding means 6 arranged in parallel, the work W to be processed suitable for the rough grinding independent layout or the fine grinding independent layout is as follows.

In other words, when grinding a wafer (upper layer) in which a soft protective tape (lower layer) is attached to the back surface as the work W, the thickness variation of the protective tape is directly related to the thickness variation of the processed work W, and hence it is preferable to reduce the thickness variation of the processed work W by making the displacement generated in the index table 2 and the base 4 as equal as possible. Note that the protective tape is made of, for example, resin. Furthermore, “soft” means a flexible property of an extent the protective tape elastically deforms at the time of grinding.

Therefore, when grinding a wafer attached with a soft protective tape, the rough grinding independent layout in which the displacement of the index table 2 and the base 4 is relatively small is preferable.

On the other hand, when grinding a wafer (upper layer) in which the back surface is supported by a hard support substrate (lower layer) as the work W, the wafer is processed to be extremely thin to a film thickness of less than or equal to 10 μm, and the wafer may brake due to the load caused by the vibration at the time of grinding, and hence the damages on the work W are preferably avoided as much as possible. Note that the support substrate is made of, for example, silicon, glass, hard resin, or the like. Furthermore, “hard” means a hard property of an extent the support substrate can support an extremely thin wafer at the time of grinding.

Therefore, when grinding a wafer supported by the hard support substrate, a fine grinding independent layout in which the propagated vibration from the medium grinding means 6 to the fine grinding means 7 is relatively small is preferable. Similarly, even when grinding a hard wafer that does not include the support substrate, a fine grinding independent layout in which the propagated vibration from the medium grinding means 6 to the fine grinding means 7 is relatively small is preferable.

In this manner, the processing device 1 according to the present embodiment is a processing device 1 that performs rough grinding, medium grinding and fine grinding on the work W in order, and is configured to include an index table 2 that includes a plurality of chucks 22 for adsorbing and holding the work W and transports the work W in the order of a rough grinding stage S2 provided with a rough grinding means 5 for rough grinding the work W, a medium grinding stage S3 provided with a medium grinding means 6 for medium grinding the work W, and a fine grinding stage S4 provided with a fine grinding means 7 for fine grinding the work W; a first column 31 provided to extend over the index table 2 and in which one of the rough grinding means 5 or the fine grinding means 7 is installed; and a second column 32 provided to extend over the index table 2 and provided independent from the first column 31, and in which the medium grinding means 6 is installed and the other one of the rough grinding means 5 or the fine grinding means 7 is arranged parallel to the medium grinding means 6.

According to such a configuration, the first column 31 and the second column 32 are provided independent from each other, the rough grinding means 5 that generates large displacement in the processing device 1 by reaction at the time of processing is provided on one of the first column 31 or the second column 32, and the fine grinding means 7 that greatly affects the finish shape of the work W is provided on the other one of the first column 31 or the second column 32, so that the work W can be processed with a satisfactory precision.

Furthermore, according to the processing device 1 of the present embodiment, in a case where the work W is a wafer in which the soft protective tape is attached, the rough grinding means 5 is provided on the first column 31 and the fine grinding means 7 is provided on the second column 32.

According to such a configuration, the deviation in displacement generated in the index table 2 and the base 4 is suppressed, and hence the thickness variation of the soft protective tape can be reduced and the work W can be processed with a satisfactory precision.

Furthermore, according to the processing device 1 of the present embodiment, in a case where the work W is a wafer supported by a hard support substrate, the fine grinding means 7 is provided on the first column 31 and the rough grinding means 5 is provided on the second column 32.

According to such a configuration, the vibration generated in the rough grinding means 5 and the medium grinding means 6 is suppressed from being propagated to the fine grinding means 7, and thus the work W that is extremely thin and easily breakable can be stably processed.

The processing device 1 according to the present embodiment has a configuration in which the index table 2 is configured to be rotatable in a clockwise direction and a counterclockwise direction when viewed in a plane.

According to such a configuration, the index table 2 can change the rotating direction according to the layout of the rough grinding means 5 and the fine grinding means 7, and thus the work W can be transported in the order of the rough grinding, the medium grinding, and the fine grinding.

The present invention can be variously modified within a scope not deviating from the spirit of the present invention, and it should be apparent that the present invention encompasses all such modifications.

### INDUSTRIAL APPLICABILITY

### Description of Symbols

1 processing device
2 index table
21 rotation shaft
22 chuck
23 partition plate
3 main unit
31 first column
32 second column
33 base portion
33a rear surface
34 supporting column
35a groove
35b groove
35c far surface
36 base portion
36a front surface
37 supporting column
38a groove
38b groove
38c far surface
38d far surface
4 base
5 rough grinding means
51 rough grinding stone
52 first spindle
53 first spindle feeding mechanism
54a front guide
54b rear guide
55 first constant-pressure cylinder
6 medium grinding means
61 medium grinding stone
62 second spindle
62a saddle
63 second spindle feeding mechanism
63a nut
63b ball screw
63c motor
64a front guide
64b rear guide
65 second constant-pressure cylinder
7 fine grinding means
71 fine grinding stone
72 third spindle
73 third spindle feeding mechanism
74a front guide
74b rear guide
75 third constant-pressure cylinder
D feeding direction
O rotation axis
P1 processing point
S1 transport in/out stage
S2 rough grinding stage
S3 medium grinding stage
S4 fine grinding stage
W work

What is claimed is:

1. A processing device that performs rough grinding, medium grinding and fine grinding on a work in order, the processing device comprising:
an index table that includes a plurality of chucks for adsorbing and holding the work, and transports the work in order of a rough grinding stage provided with a rough grinding means for rough grinding the work, a medium grinding stage provided with a medium grinding means for medium grinding the work, and a fine grinding stage provided with a fine grinding means for fine grinding the work;
a first column provided to extend over the index table and in which one of the rough grinding means or the fine grinding means is installed; and
a second column provided to extend over the index table and provided independent from the first column, and in which the medium grinding means is installed and the other one of the rough grinding means or the fine grinding means is arranged parallel to the medium grinding means.

2. The processing device according to claim 1, wherein
the rough grinding means is provided on the first column;
the fine grinding means is provided on the second column: and
the work is subjected to fine grinding in a state where the index table is displaced substantially equally in the fine grinding stage.

3. The processing device according to claim 1, wherein
the fine grinding means is provided on the first column;
the rough grinding means is provided on the second column; and
the work is subjected to fine grinding in a state where propagated vibration from the medium grinding means to the fine grinding means is reduced.

4. The processing device according to claim 1, wherein the index table is configured to be rotatable in a clockwise direction and a counterclockwise direction when viewed in a plane.

5. The processing device according to claim 2, wherein the index table is configured to be rotatable in a clockwise direction and a counterclockwise direction when viewed in a plane.

6. The processing device according to claim 3, wherein the index table is configured to be rotatable in a clockwise direction and a counterclockwise direction when viewed in a plane.

7. A processing device that performs rough grinding, medium grinding and fine grinding on a work in order; the processing device comprising:
an index table that includes a plurality of chucks for adsorbing and holding the work, and transports the work in order of a rough grinding stage provided with a rough grinding stone, a medium grinding stage provided with a medium grinding stone, and a fine grinding stage provided with a fine grinding stone;
a first column provided to extend over the index table and in which one of the rough grinding stone or the fine grinding stone is installed; and
a second column provided to extend over the index table and provided independent from the first column, and in which the medium grinding stone is installed and the other one of the rough grinding stone or the fine grinding stone is arranged parallel to the medium grinding stone.
